(19) United States
(12) Patent Application Publication
(10) Pub. No.: US 2014/0137930 A1
(43) Pub. Date: May 22, 2014

(54) MULTIJUNCTION SOLAR CELLS

(71) Applicant: SOLAR JUNCTION CORPORATION, San Jose, CA (US)

(72) Inventors: DANIEL DERKACS, SUNNYVALE, CA (US); REBECCA JONES-ALBERTUS, MOUNTAIN VIEW, CA (US); VIJIT SABNIS, CUPERTINIO, CA (US); FERRAN SUAREZ, SAN JOSE, CA (US)

(73) Assignee: SOLAR JUNCTION CORPORATION, San Jose, CA (US)

(21) Appl. No.: 14/080,612

(22) Filed: Nov. 14, 2013

Related U.S. Application Data
(60) Provisional application No. 61/727,636, filed on Nov. 16, 2012.

(51) Int. Cl. H01L 31/0735; H01L 31/18; H01L 31/0725

(52) U.S. Cl. CPC H01L 31/0735; H01L 31/0725; H01L 31/184
USPC 136/255; 438/93

(57) ABSTRACT

High efficiency multijunction solar cells formed primarily of III-V semiconductor alloys and methods of making high efficiency multijunction solar cells are disclosed.

This application claims the benefit under 35 U.S.C. §119(e) of U.S. Provisional Application No. 61/727,636 filed on Nov. 16, 2012, which is incorporated by reference in its entirety.

### FIELD

The present invention relates to solar cells, and in particular to high efficiency, multijunction solar cells formed primarily of III-V semiconductor alloys.

### BACKGROUND

It is well known in the field of space and concentrated photovoltaics, using high efficiency, multijunction solar cells, that price reduction remains a main focus for increasing the market for solar energy. One approach to reduce solar energy cost is to reduce cell manufacturing costs while increasing cell efficiency and maintaining material quality. Currently, the most successful technology in increasing solar cell efficiency has focused on building multi-junction solar cells. While it is clear to those skilled in the art that higher efficiencies can be reached by stacking more subcell junctions onto the solar cell to capture a wider range of the solar spectrum, building four, five and six junction cells beyond the currently market available three junction cell remains a cumbersome and expensive task. Current commercial multijunction solar cells reach a maximum record efficiency of slightly over 44%.

Materials typically used in the art for multijunction solar cells are made from III-V semiconductor alloys, grown on various substrates including Germanium, Gallium Arsenide, Silicon, or Indium Phosphide. III-V alloys are drawn from columns IIIA and VA of the standard periodic table, identified hereinafter by their standard chemical symbols, names and abbreviations, and wherein the total number of elements from column IIIA is substantially equal to the total number of elements from column VA. “III-AsNV” materials are herein defined to be alloys of elements from group IIIA (i.e., B, Al, Ga, In, Tl) and group VA (i.e., N, P, As, Sb, Bi) of the periodic table, which alloys include As, N and at least one additional element from Sb and Bi.

III-V semiconductor atoms are typically arranged in a well-defined three dimensional configuration referred to as a lattice. Lattice matching refers two different materials which have the same atomic spacing and structure and thus form a coherent interface. This scenario is ideal since there are no extra or missing bonds between atoms and the high quality crystal-nature of the two materials is maintained. It is to be noted in the following application that the general understanding of “substantially lattice matched” is that the in-plane lattice constants of the materials in their fully relaxed states differ by less than 0.6% when the materials are present in thicknesses greater than 100 nm. Further, subcells that are substantially lattice matched to each other as used herein means that all materials in the subcells that are present in thicknesses greater than 100 nm have in-plane lattice constants in their fully relaxed states that differ by less than 0.6%. Lattice mismatching occurs when two materials have different atomic spacing.

To integrate different materials into a multijunction solar cell, different optimal thermal treatments are desired. Select materials need specific thermal treatment, substrate growth, and/or substrate orientation in order to achieve optimal material quality. As an example, the growth process required to create the Ge subcell used in many multi junction solar cells needs to be carefully controlled to achieve its optimum material quality. Therefore, given the different requirements needed to achieve optimal performance of a select material, it is advantageous to grow and effectively group together those materials that can withstand a certain anneal process and/or growth and later integrate them into a multijunction solar cell.

In particular, for multijunction solar cells incorporating dilute nitride subcells, in-situ or post-growth annealing is required to achieve reliable material performance. This high temperature anneal may affect the performance of some neighboring materials. Further, advanced four, five, six or more junction multijunction solar cells may be implemented with multiple dilute nitride subcells with each dilute nitride subcell possessing a different bandgap. These different bandgap dilute nitride subcells may require different annealing processes in order for each junction to perform optimally. In this case, it would be advantageous to the overall quality of all the materials for the subcells in the multijunction solar cell for the individual dilute nitride subcells to be grown on different substrates and receive its optimal thermal treatment. For example, the bonding technique could potentially allow the use of different anneal treatments for the bottom diffuse cell (Ge) and for the triple junction structure to be bonded on top. This approach can permit optimization of the growth technique, for example, growth of the triple stack of MBE and the bottom cell by MOCVD. While cell efficiency improvement is one side of the cost equation for CPV, the cost associated with growing techniques and material use remains the other. Those skilled in the art use either a molecular beam epitaxy (MBE) or metal organic chemical vapor deposition (MOCVD) process for epitaxial growth. While MBE has been shown to produce the highest performance multi junction solar cells, MOCVD is a commonly used method in the industry that can be cost advantageous depending on the subcells grown. Combining both the MOCVD and MBE growth processes—instead of using just MBE or MOCVD—may be cost-effective for multijunction solar cells with 4, 5, or 6 or more subcells.

Further, substrates used to grow certain subcells can be costly. It would be advantageous to reuse non-epitaxial substrates in order to produce additional subcell growths.

Each subcell in this application comprises several associated layers, typically including a window, emitter, base and back surface field (BSF). These terms are well known to those skilled in the art and do not need further definition here. Each of the foregoing layers may itself include one or more sublayers. The window and emitter will be of one doping polarity (e.g., n-type) and the base and back surface field will be of the opposite polarity (e.g., p-type), with a p-n or n-p junction formed between the base and the emitter. If the base contains an intrinsic region in addition to an intentionally doped region, then it may be considered a p-i-n or n-i-p junction, as is well known to those skilled in the art. By convention, the specific alloy and the band gap of a given subcell are considered to be the name and the band gap, respectively, of the material forming the base. This material may or may not also compose the window, emitter and back surface field of the subcell. For example, a subcell comprising an AlInP window, an InGaP emitter, a GaAs base and an AlGaAs back surface field would be denoted a GaAs subcell. A subcell comprising an AlInP window, an InGaP emitter, an InGaP base and an InGaP back surface field would be denoted an InGaP subcell. The subcell may include layers in addition to those listed above. Those skilled in the art will also recognize that subcells may also be constructed without one or more of the foregoing layers. For example, subcells may be constructed without a window or without a back surface field.

When referring to the stacking order of the subcells from top to bottom, the top subcell is defined to be the subcell closest to the light source during operation of the solar cell, and the bottom subcell is furthest from the light source. Relative terms like “above,” “below,” “upper,” and “lower” also refer to position in the stack with respect to the light source. The order in which the subcells were grown is not relevant to this definition. The top subcell is also denoted “J1,” with “J2” being the second subcell from the top, “J3” being third from the top, and the highest number going to the bottom subcell.

While there has been recent interest in using wafer bonding to create multijunction solar cells, prior art in the field has not taught that this work can be applied to III-AsNV subcells substantially lattice-matched to the substrate they are grown on, such as a Ge or GaAs substrate (herein described as “lattice matched III-AsNV”). Prior work in this field have included wafer-bonding of lattice-mismatched subcells, including GaInAs and GaInP grown on Ge and later bonded to Si, or, InGaAs, InGaAsP, GaAs, and GaInP grown on InP and later bonded to Si. See Law et al., Solar Energy Materials & Solar Cells, 94(2010) October 2008, pp. 1314-1318. Or, alternatively, it has been demonstrated that a four junction solar cell can be fabricated using wafer bonding with InGaAsP and InGaAs as the bottom two junctions and with GaAs and InGaP as the upper two junctions. See Szabo et al., Phys. Stat. Sol. (RRL) 2, No. 6 July, 2008, pp. 254-256. Or, further, that four junction solar cells may be produced via wafer bonding by growing AlInGaP and GaAs on GaAs and InGaAsP and InGaAs on InP and bonding the AlInGaP, GaAs, InGaAsP, and InGaAs on either substrates InP or Si. See Zahler et al., Applied Physics Letters, 91, 012108, 2007. None of the prior art, however, including those described above, have taught that lattice-matched III-AsNV can be incorporated in a multijunction solar cell or that this lattice-matched III-AsNV can be wafer bonded. Because III-AsNV materials differ from more traditional semiconductors in many of their properties, such as their large band gap bowing parameter, it is not obvious that the above described techniques used with more traditional solar cells should be applied to III-AsNV materials. Or, as the work of Ptak et al. in the Journal of Vacuum Science Technology, B 25(3), May/June 2007, pp. 955-959 teaches, lattice-matched solar cells with GaInNAs, fabricated using the known techniques in the field, has been historically dismissed in the art as exhibiting poor material quality.

Prior work in this general field demonstrates that a high level of skill in the art exists for making materials, so that it is not necessary to disclose specific details of the processes of making the materials for use in solar cells. Several representative U.S. patents are exemplary. U.S. Pat. No. 6,281,426 discloses certain structures and compositions without disclosing fabrication techniques and refers to other documents for guidance on growth of materials. U.S. Pat. No. 7,727,795 relates to inverted metamorphic structures for solar cells in which exponential doping is disclosed.

### SUMMARY

The following invention delineates a method of fabricating substantially lattice-matched subcells comprising at least one III-AsNV alloy to optimize annealing environments by grouping together lattice-matched subcells based on similar optimal annealing temperatures and later integrating the grouped subcells into a multijunction solar cell having four or more subcells. Specifically, the invention describes embodiments for which multiple groupings of subcells of a multijunction solar cell are grown lattice matched to Si, SiGe, GaAs, Ge, InP or virtual substrate. A virtual substrate refers to a material in which one or more epitaxial layers are grown on a substrate characterized by a substantially different lattice constant than that of the epitaxial layer, such as, for example, Ge grown on Si.

The invention also describes diffusion processes, using P and As dopants, to create an n-p or p-n junction in a Ge substrate and forming multiple subcells on top of the doped Ge substrate by a wafer bonding method.

The invention further describes several embodiments of four, five, and six junction lattice-matched multi junction solar cells for which at least some of the subcells are grown on two or more substrates, and the two or more substrates subsequently bonded together in a manner that optimizes the performance of the final multijunction solar cell. In several embodiments described herein, groupings of subcells grown on a substrate by either MBE or MOCVD may be annealed in-situ and/or post-growth at one or more temperatures so as to optimize the performance of the grouped subcells and the multijunction solar cell.

In a first aspect multijunction solar cells are disclosed, comprising a first group of one or more subcells; and a second group of one or more subcells, wherein each of the subcells is lattice matched to a second substrate; wherein, the second group of subcells is bonded to the first group of subcells; the multijunction solar cell comprises at least three subcells; and at least one of the at least three subcells comprises a base layer comprising an alloy of elements of group IIIA, group IV, and group VA on the periodic table.

In a second aspect, methods of manufacturing a multijunction solar cell are disclosed, comprising forming a first group of one or more subcells; forming a second group of one or more subcells, wherein each of the one or more subcells is lattice matched to a second substrate; thinning the second substrate; and bonding the thinned second substrate to a top subcell of the first group of subcells, to form a multijunction solar cell; wherein, the multijunction solar cell comprises at least three subcells; and at least one of the at least three subcells comprises a base layer comprising an alloy of elements of group IIIA, group IV, and group VA on the periodic table.

In a third aspect, methods of manufacturing a multijunction solar cell are disclosed, comprising, forming a first group of one or more subcells; forming a second group of one or more subcells overlying a release layer, wherein the release layer overlies a second substrate, and each of the one or more subcells is lattice matched to the second substrate; attaching a carrier substrate to a top subcell of the second group of subcells; releasing the second group of subcells from the second substrate; and bonding the second group of subcells to a top subcell of the first group of subcells, to form a multijunction solar cell; wherein, the multijunction solar cell comprises at least three subcells; and at least one of the at least three subcells comprises a base layer comprising an alloy of elements of group IIIA, group IV, and group VA on the periodic table.

The invention will be better understood by referencing the following detailed description in connection with the accompanying figures, which constitute the drawings.

### BRIEF DESCRIPTIONS OF THE DRAWINGS

FIG. 1A shows a method of manufacturing a multijunction solar cell according to certain embodiments of the invention in which the subcells are not inverted.

FIG. 1B shows a method of manufacturing a multijunction solar cell according to certain embodiments of the invention in which the subcells are not inverted.

FIG. 1C shows a method of manufacturing a multijunction solar cell according to certain embodiments of the invention in which the subcells are not inverted.

FIG. 1D shows a method of manufacturing a multijunction solar cell consistent with the methods shown in FIGS. 1A, 1B, and 1C and where the subcells are bonded to an epitaxial Ge subcell on a Si substrate.

FIG. 1E shows a method of manufacturing a multijunction solar cell consistent with the methods shown in FIGS. 1A, 1B, and 1C and where the subcells are bonded to an epitaxial SiGe subcell on a GaAs substrate.

FIG. 2A shows a method of manufacturing a multijunction solar cell according to certain embodiments of the invention in which the subcells are inverted.

FIG. 2B shows a method of manufacturing a multijunction solar cell according to certain embodiments of the invention in which the subcells are inverted.

FIG. 2C shows a method of manufacturing a multijunction solar cell consistent with the methods shown in FIGS. 2A and 2B and where the subcells are bonded to an epitaxial Ge subcell on a Si substrate.

FIG. 2D shows a method of manufacturing a multijunction solar cell consistent with the methods shown in FIGS. 2A and 2B and where the subcells are bonded to an epitaxial SiGe subcell on a GaAs substrate.

FIG. 3A a method of manufacturing a multijunction solar cell consistent with the embodiments shown in FIGS. 1A, 1B, 1C, 2A, and 2B on separately annealed III-AsNV/diffused Ge (separate anneal).

FIG. 3B a method of manufacturing a multijunction solar cell consistent with the embodiments shown in FIGS. 1A, 1B, 1C, 2A, 2B on separately annealed III-AsNV/Ge-on-Si.

FIG. 3C a method of manufacturing a multijunction solar cell consistent with the embodiments shown in FIGS. 1A, 1B, 1C, 2A, 2B on separately annealed III-AsNV and were the subcells are bonded to an epitaxial SiGe subcell on a GaAs substrate.

FIG. 4A shows a method of manufacturing a multijunction solar cell comprising a As n+ region and a p-type Ge substrate according to certain embodiments.

FIG. 4B shows a method of manufacturing a multijunction solar cell comprising an As-containing layer according to certain embodiments.

FIG. 4C shows a method of manufacturing a multijunction solar cell according to certain embodiments.

FIG. 4D: shows a method of manufacturing a multijunction solar cell according to certain embodiments.

FIG. 5A shows a method of manufacturing a multijunction solar cell comprising an InGaP, InP, or GaP layer and a phosphorous diffused n+ region according to certain embodiments.

FIG. 5B shows a method of manufacturing a multijunction solar cell comprising an InGaP, InP, or GaP layer and a phosphorous diffused n+ region according to certain embodiments.

FIG. 5C shows a method of manufacturing a multijunction solar cell comprising an InGaP, InP, or GaP layer and a phosphorous diffused n+ region according to certain embodiments.

### DETAILED DESCRIPTION

### Upright Growth Method

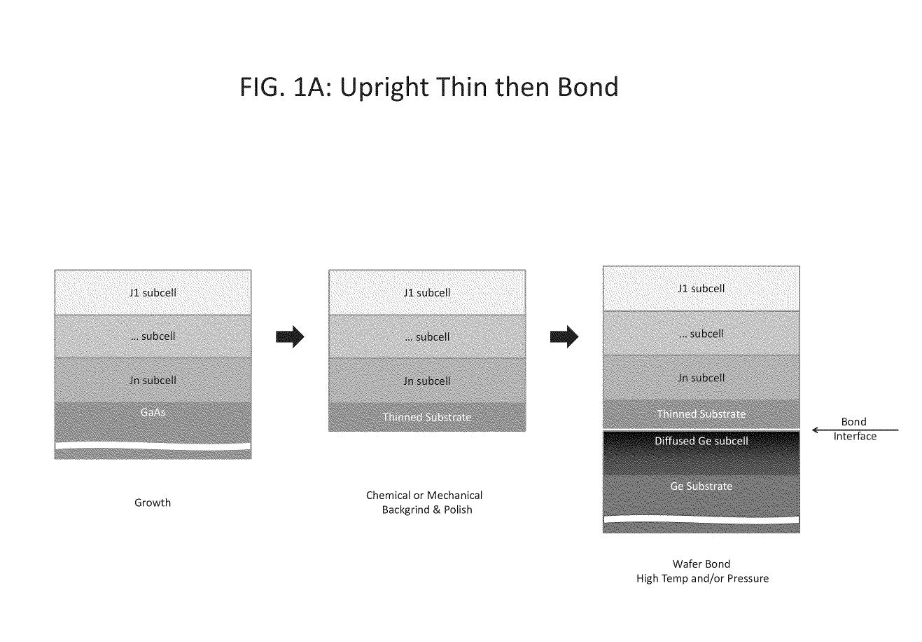

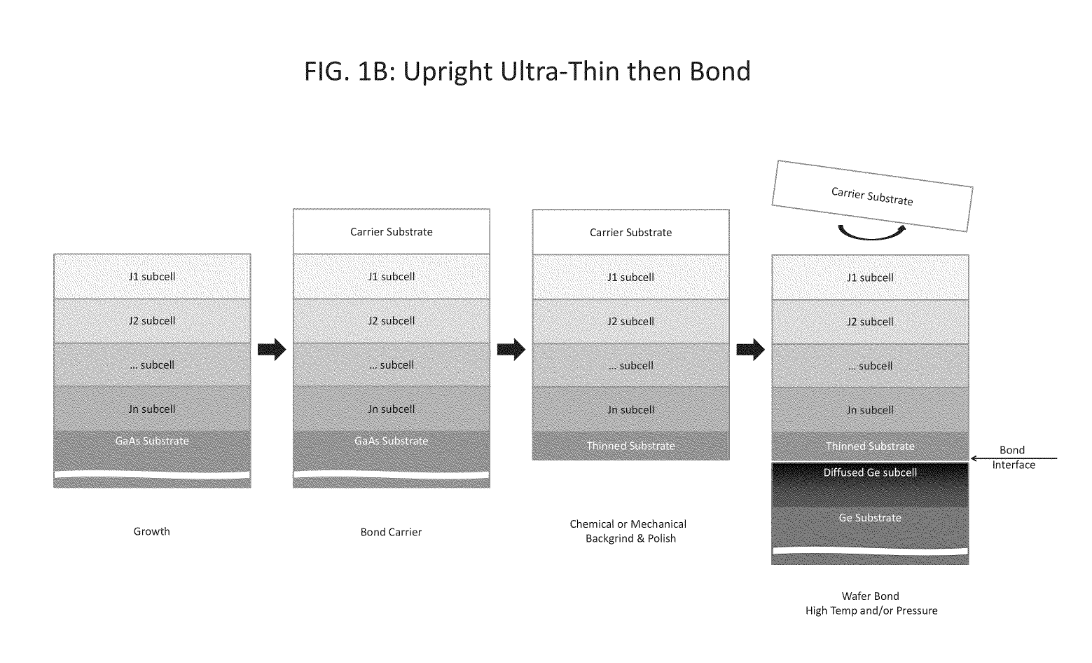

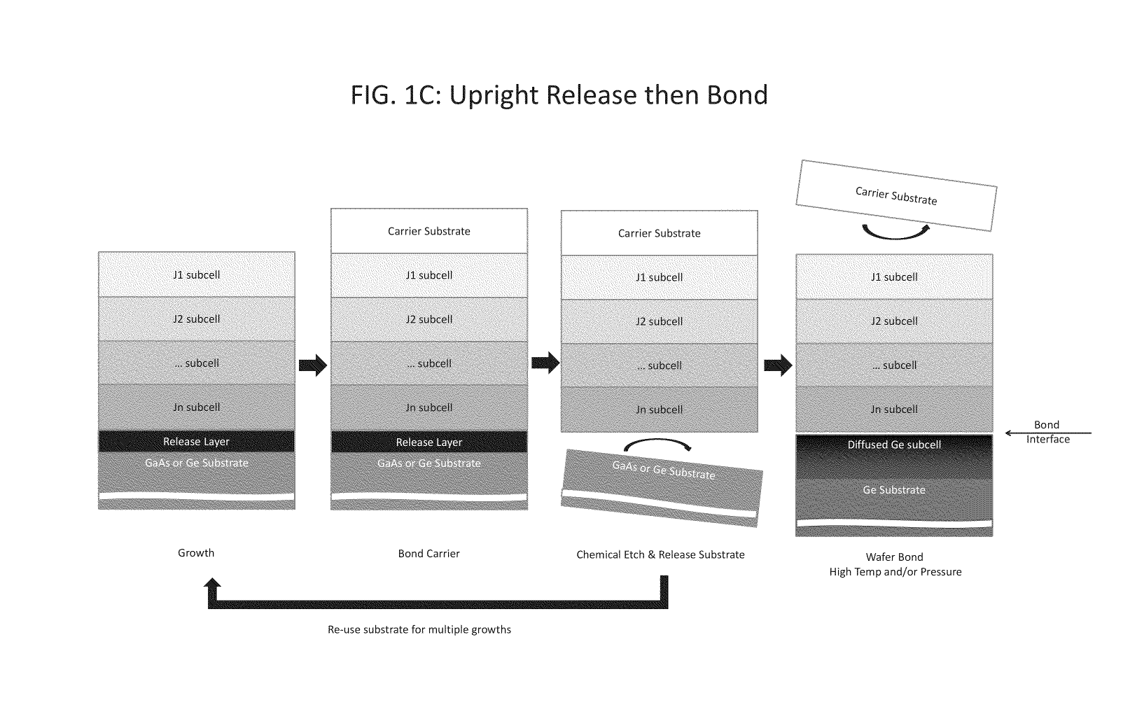

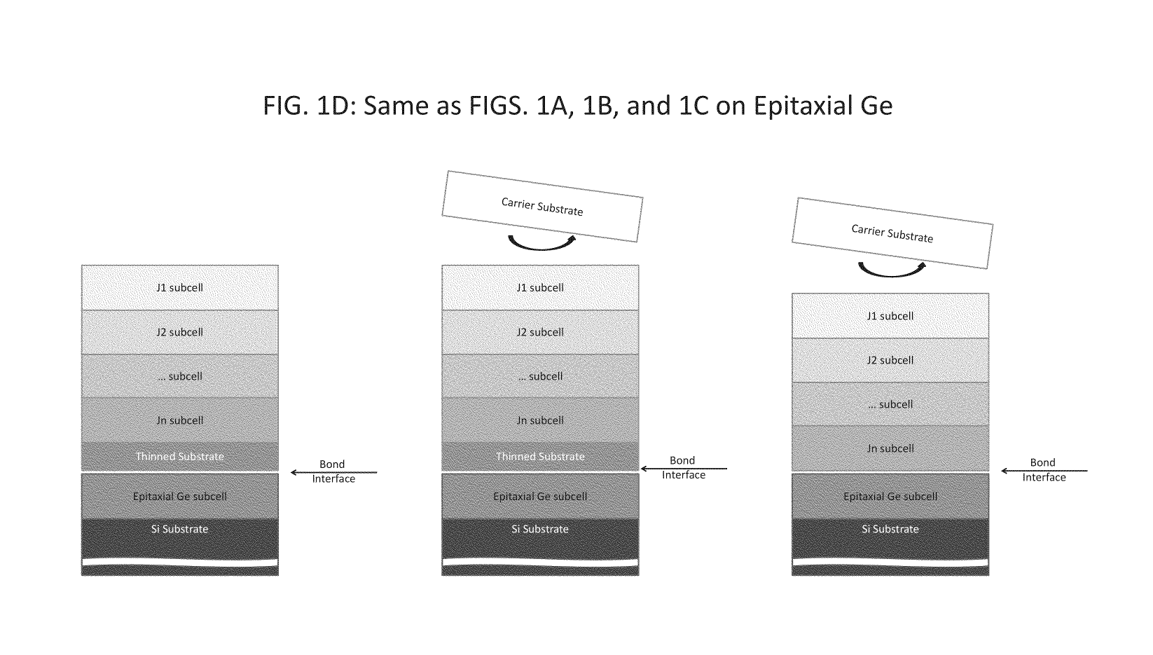

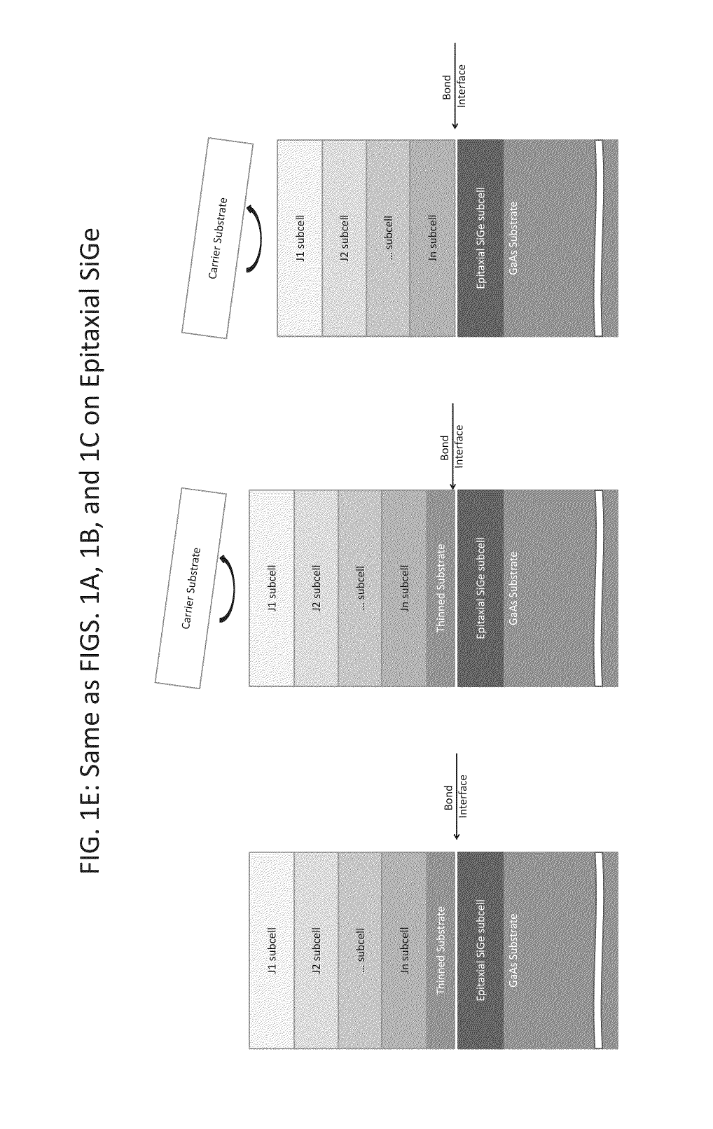

FIG. 1A shows an embodiment of a process of the invention depicting multiple subcells (herein described as “subcell stack” or “substructure”), in particular two or more subcells, grown on a GaAs or Ge substrate. The GaAs substrate is thinned by a chemical or mechanical back-grind and then polished to a surface flatness of less than one nm, a process which is well known by those skilled in the art. Those skilled in the art will know that many chemical and mechanical back-grind processes are available. In some embodiments, the GaAs substrate is thinned to 50 microns, in other embodiments, from 50 microns up to 200 microns, and in yet other embodiments from 200 microns up to 650 microns. The subcell stack grown on top of the GaAs substrate, after being thinned, can then be wafer bonded on top of a Ge subcell incorporating a Ge substrate using processes well known to those skilled in the art. For example, FIG. 1A shows subcells J1 to Jn grown on a GaAs substrate. The GaAs substrate is then thinned. In the final step, the subcells J1 to Jn on the thinned GaAs substrate are bonded to a Ge subcell incorporating a Ge substrate. The bonding of the thinned GaAs substrate to the upper surface of the Ge subcell may be accomplished using any suitable wafer bonding method such as, high temperature bonding, pressure bonding, or a combination of both.

Another embodiment of a process of the invention is shown in FIG. 1B. FIG. 1B depicts multiple subcells J1 to Jn, grown on a GaAs or a Ge substrate. A carrier substrate is then attached to the top-most subcell J1 of the entire structure before chemically or mechanically thinning and polishing the underlying GaAs or Ge substrate. The carrier substrate may comprise another semiconductor, plastic, ceramic, or any other rigid or flexible material and can be attached using wax or any number of other methodologies well known to those skilled in the art and is used in the process of transferring the subcell stack to be bonded to other subcell(s) grown on a different substrate, such as Ge or GaAs described above.

FIG. 1B represents a process with several embodiments. In some embodiments, the GaAs or Ge substrate is thinned to a thickness from 1 microns to 10 microns, and in other embodiments, from 10 microns up to 50 microns. The thickness of the thinned substrate is selected to minimize absorption of incident solar radiation. After the GaAs or Ge substrate is thinned to a suitable thickness the assembly comprising the carrier substrate, subcells and thinned substrate are wafer bonded to a second subcell stack. In FIG. 1B, this subcell stack is a Ge subcell incorporating a Ge substrate. After wafer bonding, the carrier substrate can be removed using a number of processes well known to those skilled in the art. One such process may be a heat treatment that releases the semiconductor from the carrier substrate.

In other embodiments, instead of thinning the Ge or GaAs substrate and continuing with the procedure as shown in FIG. 1B, a release layer, which may comprise AlAs, InAlP, InGaP, AlInGaP and/or AlGaAs is grown on top of a Ge or GaAs substrate. In certain embodiments, the Al concentration in the release layer forms 25% to 100%, or in certain embodiments 50%-100%, or in yet other embodiments 80%-100% of the composition. After attaching a carrier substrate to the top subcell, the Ge or GaAs substrate is chemically released using, for example, hydrofluoric acid. The substrate may then be re-used for multiple growths. The three or more subcells, after being released from the substrate, are then wafer bonded on top of a diffused Ge subcell incorporating a Ge substrate. The carrier substrate is then removed from the top of the structure. This process is shown in FIG. 1C.

In the above processes, described in FIG. 1A, 1B, and 1C, the subcell stack grown on top of a Ge or GaAs substrate, after being thinned or released by the methods described, can also be wafer bonded on top of an epitaxial Ge subcell, serving as an active junction, on a Si substrate, as depicted by FIG. 1D (herein referred to as a “Ge-on-Si carrier substrate”). The Ge-on-Si carrier substrate, using an active Ge junction, may be fabricated using a number of methods known to those skilled in the art such as wafer bonding, buffer layering, metamorphically, etc. In other embodiments, this subcell stack can be wafer bonded on top of an epitaxial SiGe subcell on a GaAs substrate, as depicted by FIG. 1E.

In a specific example of the above described structures, one subcell of the subcell stack includes at least one III-AsNV subcell, grown on a GaAs or Ge substrate. The bottom most subcell in the subcell stack is a III-AsNV subcell. A release layer may first be attached to the GaAs or Ge substrate before growing the bottommost subcell. The subcells including the at least one III-AsNV subcell are then bonded to an InGaAs subcell grown separately on top of an InP substrate. The subcell stack including the III-AsNV subcell(s) may be annealed before bonding to the InGaAs subcell and/or after bonding to the InGaAs subcell. The InGaAs subcell has a band gap in the range of 0.7-0.8 eV. In a specific three junction solar cell embodiment using the above described procedures, a release layer, which may comprise AlAs or AlGaAs with an Al composition of 80-100%, can be grown on top of a Ge or GaAs substrate which is used to later remove the Ge or GaAs substrate as shown in the process of FIG. 1C. A subcell comprising Al(In)GaAs or (In)GaAs can be grown on the release layer, and another subcell comprising (Al)InGaP or InGaP can then be grown on the Al(In)GaAs or (In)GaAs subcell. A carrier substrate may then be bonded to the top of the subcell stack, or on top of the (Al)InGaP subcell in some embodiments or on top of the InGaP in other embodiments. Chemical etching can be used to remove the first subcell stack of two subcells from the Ge or GaAs substrate. Using the carrier substrate to transfer the subcell stack, the subcells can then be bonded onto, for example, a Si subcell grown on a Si substrate. The carrier substrate can then be removed using the described well-known processes. The Ge or GaAs substrate can be cost-effectively reused for other subcell growth.

In a related embodiment, three or more subcells are bonded to the top of a Si subcell grown on a Si substrate to create a four, five, or six junction solar cell. In one embodiment, one or two III-AsNV subcells can be bonded to the top of the Si subcell, though preferred embodiments will have one III-AsNV subcell in the substructure. The III-AsNV subcell(s) can be grown on a Ge or GaAs substrate that is removed before or after bonding, and may be reused. This stack of subcells may be annealed at a specific temperature before bonding to the Si subcell grown on the Si substrate to obtain the best material quality of all the subcells. In another embodiment, InGaAs, Ge, SiGe and/or III-AsNV subcells may be separately grown and bonded to a Si subcell grown on a Si substrate. A preferred three junction embodiment will have a substructure (Al)InGaP/AlGaAs/GaInNAsSb bonded to a Si substrate. Another preferred three junction embodiment will have (Al)InGaP/AlGaAs bonded onto a diffused epitaxial Si layer grown on a Si substrate. A preferred four junction embodiment will have (Al)InGaP/AlGaAs/GaInNAsSb bonded to a diffused epitaxial Si layer grown on a Si substrate.

Ga₁₋ₓInₓN_{y}As_{1-y-z}Sb_{z} compositions such as those disclosed in U.S. Application Publication No. 2010/0319764 and U.S. Application Publication No. 2013/0122638, each of which is incorporated by reference, produces high quality material when substantially lattice-matched to a GaAs or Ge substrate and in the composition range of, for example, 0.07≦x≦0.18, 0.025≦y≦0.04 and 0.001≦z≦0.03, in which the Ga₁₋ₓInₓN_{y}As_{1-y-z}Sb_{z} exhibits a bandgap of at least 0.9 eV, a short circuit current density Jsc of at least 13 mA/cm², and an open circuit voltage Voc of at least 0.3 V.

In certain embodiments, a dilute nitride subcell comprises Ga₁₋ₓInₓN_{y}As_{1-y-z}Sb_{z}, in which values for x, y, and z are 0.08≦x≦0.18, 0.025≦y≦0.04 and 0.001≦z≦0.03, with a band gap of at least 0.9 eV. In certain embodiments, a dilute nitride subcell comprises Ga₁₋ₓInₓN_{y}As_{1-y-z}Sb_{z}, in which values for x, y, and z are 0≦x≦0.24, 0.01≦y≦0.07 and 0.001≦z≦0.20; in certain embodiments, 0.02≦x≦0.24, 0.01≦y≦0.07 and 0.001≦z≦0.03; in certain embodiments, 0.02≦x≦0.18, 0.01≦y≦0.04 and 0.001≦z≦0.03; in certain embodiments, 0.08≦x≦0.18, 0.025≦y≦0.04 and 0.001≦z≦0.03; and in certain embodiments, 0.06≦x≦0.20, 0.02≦y≦0.05 and 0.005≦z≦0.02.

In certain embodiments, a dilute nitride subcell comprises Ga₁₋ₓInₓN_{y}As_{1-y-z}Sb_{z}, in which values for x, y, and z are 0≦x≦0.18, 0.001≦y≦0.05 and 0.001≦z≦0.15, and in certain embodiments, 0≦x≦0.18, 0.001≦y≦0.05 and 0.001≦z≦0.03; in certain embodiments, 0.02≦x≦0.18, 0.005≦y≦0.04 and 0.001≦z≦0.03; in certain embodiments, 0.04≦x≦0.18, 0.01≦y≦0.04 and 0.001≦z≦0.03; in certain embodiments, 0.06≦x≦0.18, 0.015≦y≦0.04 and 0.001≦z≦0.03; and in certain embodiments, 0.08≦x≦0.18, 0.025≦y≦0.04 and 0.001≦z≦0.03.

In certain embodiments, a dilute nitride subcell comprises Ga₁₋ₓInₓN_{y}As_{1-y-z}Sb_{z}, in which values for x, y, and z are 0≦x≦0.12, 0.001≦y≦0.03 and 0.001≦z≦0.10; in certain embodiments, 0≦x≦0.12, 0.001≦y≦0.03 and 0.001≦z≦0.03; in certain embodiments, 0.02≦x≦0.10, 0.005≦y≦0.02 and 0.001≦z≦0.02; in certain embodiments, 0.01≦x≦0.06, 0.005≦y≦0.015 and 0.001≦z≦0.02; and in certain embodiments, 0.01≦x≦0.08, 0.005≦y≦0.025 and 0.001≦z≦0.02.

### Inverted Growth Method

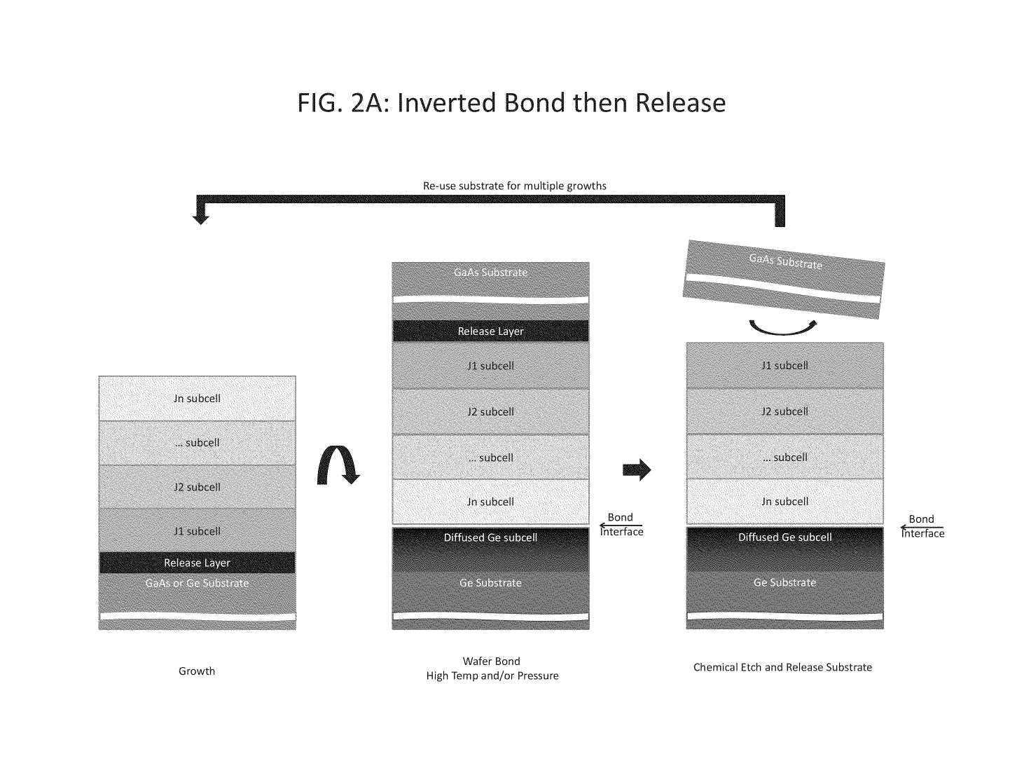

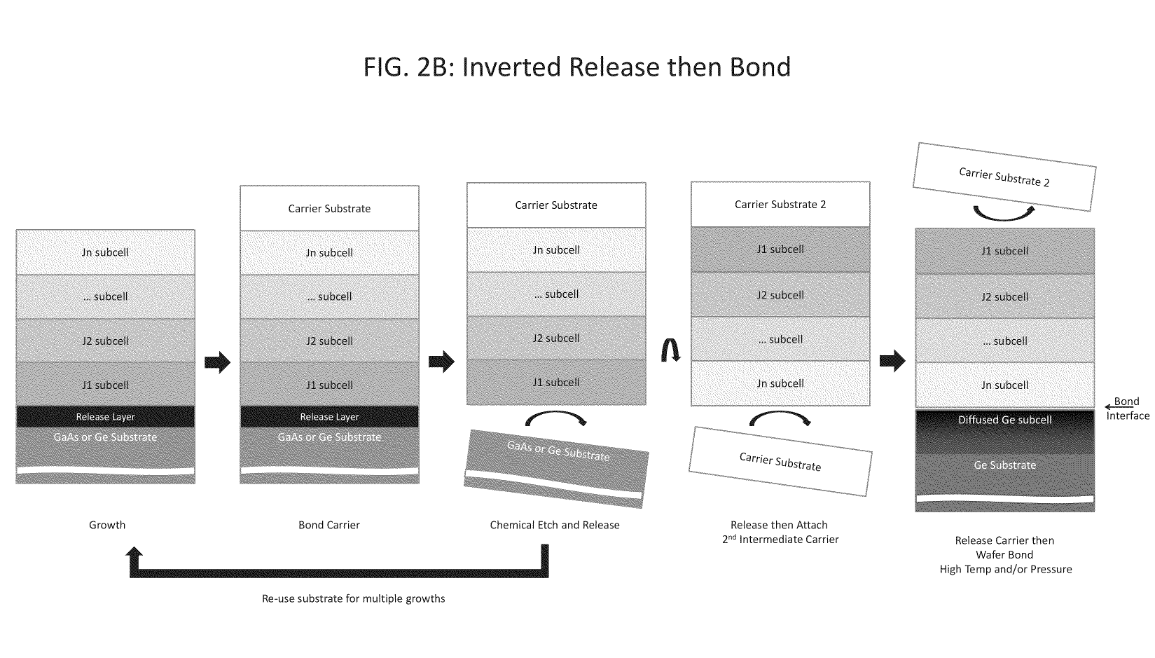

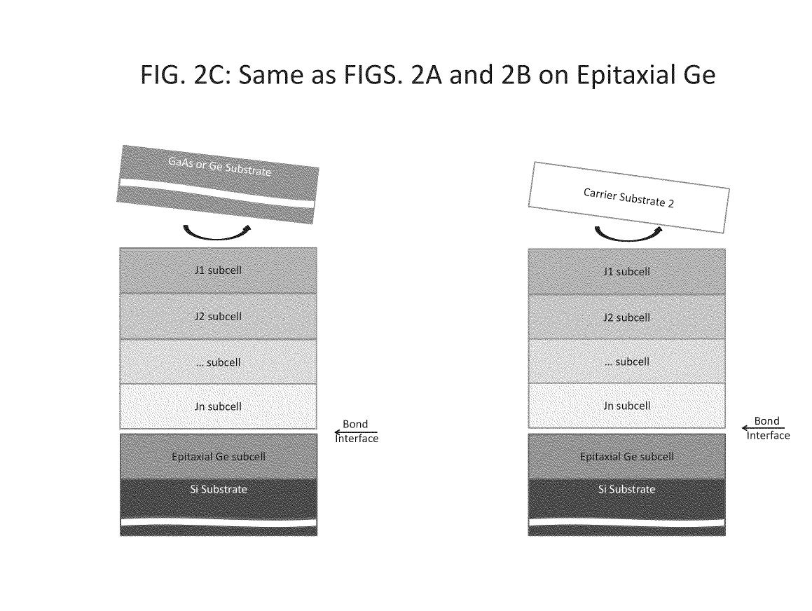

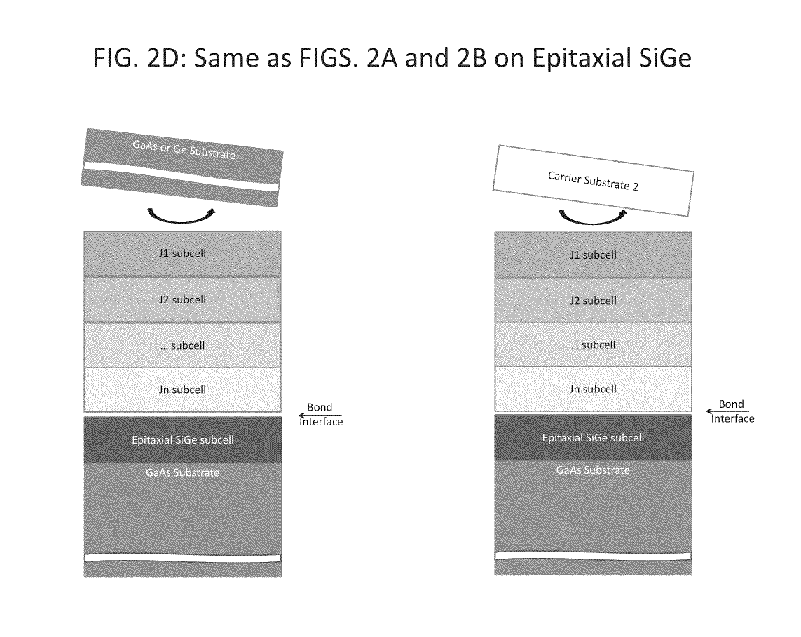

Multijunction solar cells provided by the present disclosure may also be fabricated using an inverted bond and release process as shown in FIGS. 2A, 2B, 2C, and 2D.

In each of the specific embodiments herein described in this section as shown in FIG. 2A-D, the Ge or GaAs substrate on which J1 is grown is removed using either a chemically etched release layer (“release layer”), which may comprise AlAs, InAlP, InGaP, AlInGaP and/or AlGaAs with an optimal Al composition of 25%-100% in some embodiments, 50%-100% in other embodiments, and 80%-100% in yet other embodiments, or removed using techniques known to those skilled in the art such as cleaving and/or spalling. The Ge or GaAs substrate can then be reused for other growths. In certain embodiments provided by the present disclosure, the subcells forming a multijunction solar cell are lattice-matched to each of the other subcells and to the substrate on which they are grown.

FIG. 2A shows an embodiment of the inventive process depicting multiple subcells, labeled J1 to Jn. There may be three or more subcells, grown on a GaAs or Ge substrate in an inverted fashion, such that the top subcell J1 is grown first (“inverted subcell stack”). For example, J1 is grown on a Ge or GaAs substrate, J2 is grown on top of J1, and in certain embodiments, additional subcells J3 to Jn may be grown on top of subcell J2. As shown in FIG. 2A, a release layer can be grown between the GaAs or Ge substrate and subcell J1. After the desired subcells are fabricated, the structure is then inverted and wafer bonded onto, for example, a second stack of subcells on second substrate. For example, this inverted subcell stack may be bonded onto a diffused Ge subcell incorporating a Ge substrate, such that as shown in FIG. 2, subcell Jn is bonded to the Ge subcell incorporating a Ge substrate. The original GaAs or Ge substrate, which has now been inverted, can then be released by, chemical etching or other suitable method and reused.

FIG. 2B shows an embodiment of the inventive process depicting multiple subcells, J1 to Jn grown on a Ge or GaAs substrate. According to FIG. 2B, J1 is grown on the Ge or GaAs substrate, J2 is grown on top of J1, and in other certain embodiments, additional subcells J3 to Jn are grown on J2. For example, J4 can be grown on top of the J3, and J5 can be grown on J4. As shown in FIG. 2B, a release layer can be grown between the substrate and subcells J1 and Jn. An intermediate carrier substrate can then be bonded to the uppermost subcell of the structure, Jn, after which the GaAs or Ge substrate can be chemically released and removed and reused for other growths. After removing the GaAs or Ge substrate, a second carrier substrate can be attached to subcell J1. The entire subcell stack, with the GaAs or Ge substrate removed, can then be inverted. The second carrier substrate is attached to subcell J1. The process can be completed with the second carrier substrate being attached to the subcell J1 before the subcell stack is inverted. After the subcell stack is inverted and the second carrier substrate is attached, the first intermediate carrier can be released. With the first carrier substrate released, subcell Jn is bonded to another subcell grown on a substrate such as a Ge subcell grown on a Ge substrate as shown in FIG. 2B. The second carrier substrate can then be released by any suitable method such as, for example, chemical etching.

In certain embodiments, the subcell is grown on a GaAs or Ge substrate. This GaAs or Ge substrate is released, and then the subcell stack is inverted and wafer bonded to an epitaxial Ge attached to a Si substrate or Ge-on-Si carrier substrate, as depicted in FIG. 2C. In yet other embodiments, the subcell stack can be grown on a GaAs substrate, substrate released, inverted, and wafer bonded to an epitaxial SiGe subcell on a GaAs substrate.

In certain embodiments, prior to inversion and bonding, J1 comprises the alloy AlInGaP, is grown on top of a Ge or GaAs substrate, and J2 comprises the alloy Al(In)GaAs. This structure, Al(In)GaAs/AlInGaP/(on Ge or GaAs), is inverted and bonded to a As or P diffused p-type Ge epitaxial layer grown from a Ge substrate using a thin diffusion layer. The newly doped p-type Ge substrate is referred to as the “diffused junction.” The surface of this diffusion layer may contain As, P or a combination of both As and P. This thin, epitaxially grown As or P diffusion layer may be as thin as 1 nm up to 10 nm in some embodiments, or in other embodiments greater than 10 nm, and may include alloys such as GaAs, InGaP, InP, GaP, InGaAs, or InGaAsP. After diffusion, the p-type Ge substrate is now the bottom-most junction, J4. An epitaxially grown subcell J3, which may comprise a GaInNAsSb subcell or a SiGeSn subcell on top of diffused junction, J4.

In another specific embodiment of the inverted wafer bonded stack, prior to inversion and wafer bonding AlInGaP (i.e. J1)/Al(In)GaAs (i.e. J2), and a third alloy which may comprise a III-AsNV selection from GaInNAsSb or SiGeSn (i.e. J3) is grown on top of a Ge or GaAs substrate. The subcell stack comprising, from the bottom to the top, the Ge or GaAs substrate, J1, J2, J3 is inverted and bonded to the diffused junction, J4.

In another embodiment, prior to inversion and wafer bonding, J1, which may comprise the alloy AlInGaP, is grown on top of a Ge or GaAs substrate followed by J2, which may comprise the alloy Al(In)GaAs and grown on top of J1. The structure comprising the Ge or GaAs substrate/J1/J2, is then inverted and J2 bonded onto a second stack of subcells. The second subcell stack comprises a Ge substrate that becomes the diffused, bottom-most junction, J5, and on top of which J4, which may be GaInNAsSb or SiGeSn, is grown followed by J3, which may be GaInNAsSb or SiGeSn.

In another embodiment using the diffused junction, J1, J2, J3 and J4 are bonded to the Ge or GaAs substrate and is then inverted and bonded onto what becomes the fifth and bottom-most junction, either a Ge subcell or a GaAs subcell. In this embodiment, J1 may be AlInGaP, J2 may be Al(In)GaAs, J3 may be GaInNAsSb or SiGeSn, and J4 may be GaInNAsSb or SiGeSn. J1, J2, J3 and J4 are grown from a Ge or GaAs substrate with J4 being the bottom-most subcell directly on top of the substrate.

In a further embodiment, J1, J2 and J3 are grown on top of a Ge or GaAs substrate. An exemplary embodiment may have J1 be AlInGaP, J2 be Al(In)GaAs, and J3 be GaInNAsSb or SiGeSn. This wafer is inverted and bonded to a Ge substrate that becomes a junction, J5, and on which J4, which may be GaInNAsSb or SiGeSn is grown.

In another embodiment, J1, J2, and up to Jn are grown on top of a Ge or GaAs substrate. In one embodiment, J1 comprises the alloy AlInGaP and J2 comprises the alloy Al(In)GaAs. In another embodiment, one or more additional subcells are grown on top of J2, at least one of which is a III-AsNV subcell. In yet another embodiment, J1 comprises the alloy AlInGaP, J2 comprises the alloy Al(In)GaAs, and the additional subcells up to Jn includes at least one subcell comprising a III-AsNV subcell. These embodiments are inverted and bonded to an InGaAs subcell, which may exist on a carrier substrate or on an InP, Si, GaAs or Ge substrate. In certain embodiments, J1, J2 . . . Jn are grown lattice matched to Ge or GaAs.

In a preferred, three junction solar cell embodiment using the above described methods, a release layer is grown on top of a Ge or GaAs substrate. A first subcell comprising AlInGaP or InGaP is grown on the release layer, and a second subcell comprising Al(In)GaAs or InGaAs is then grown on top of the first subcell. This lattice-matched structure comprising the substrate, the release layer, and the two subcells is then inverted and wafer bonded onto a Si subcell incorporating a Si substrate. The Ge or GaAs substrate is then removed and can be reused for other growth. In a related embodiment, a release layer is not grown, and the Ge or GaAs substrate. In a related embodiment, one or more subcells are bonded to the bottom of the Si subcell, to create a four, five or six junction solar cell. In one embodiment, one or two III-AsNV subcells, as well as a bottom contact layer (i.e., a highly conductive semiconductor layer), are bonded to the bottom of the Si subcell. The III-AsNV subcell(s) and the bottom contact layer are grown on a Ge or GaAs substrate that is removed before or after bonding to the bottom of the Si subcell. The III-AsNV subcells may be annealed before bonding. In another embodiment, InGaAs, Ge, SiGe, and/or III-AsNV subcells, as well as a bottom contact layer, may be bonded to the bottom of the Si subcell.

Several embodiments of the structures disclosed herein including those illustrated in FIG. 1A-1E and FIG. 2A-2D, can be grown using a MBE and MOCVD hybrid growth inverted method by growing the inverted and upright subcell stacks on two different substrates subject to different annealing and growth conditions. In this case, substrates and subcells that benefit from MBE growth, such dilute nitride subcells, are grown and annealed separately on a substrate, such as Ge or GaAs. Other subcells, AlGaAs, AlInGaP, InGaP, GaAs to list a few, can be grown using MOCVD on a variety of substrates. This MOCVD-MBE hybrid growth method can be used to fabricate 4, 5, 6, to Jn-junction solar cells.

### Embodiments Using Single Growth As n+ Region

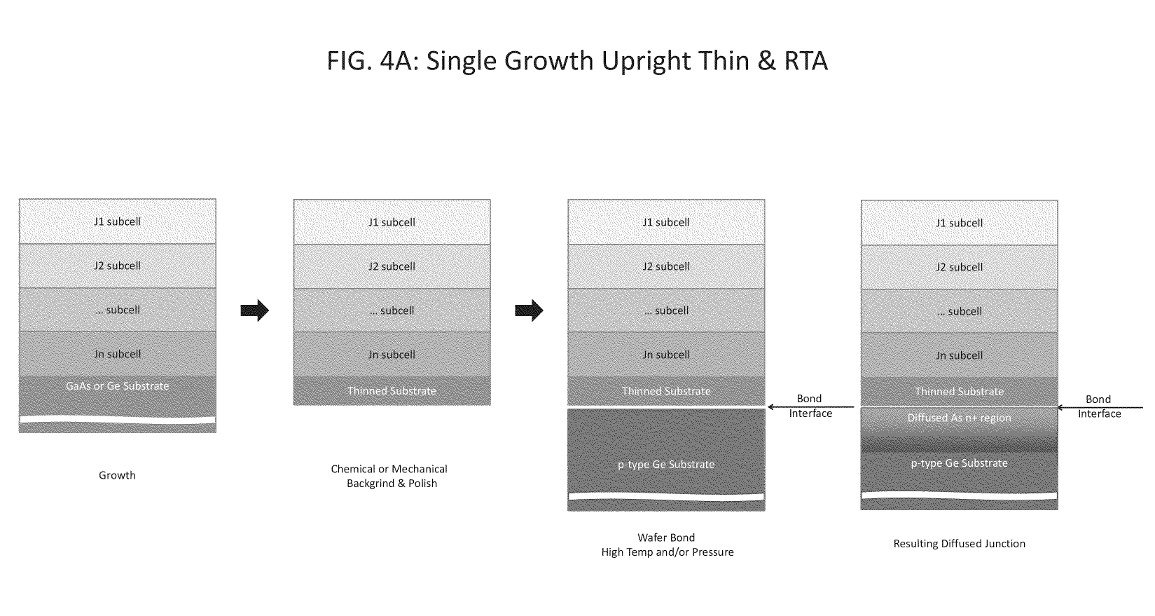

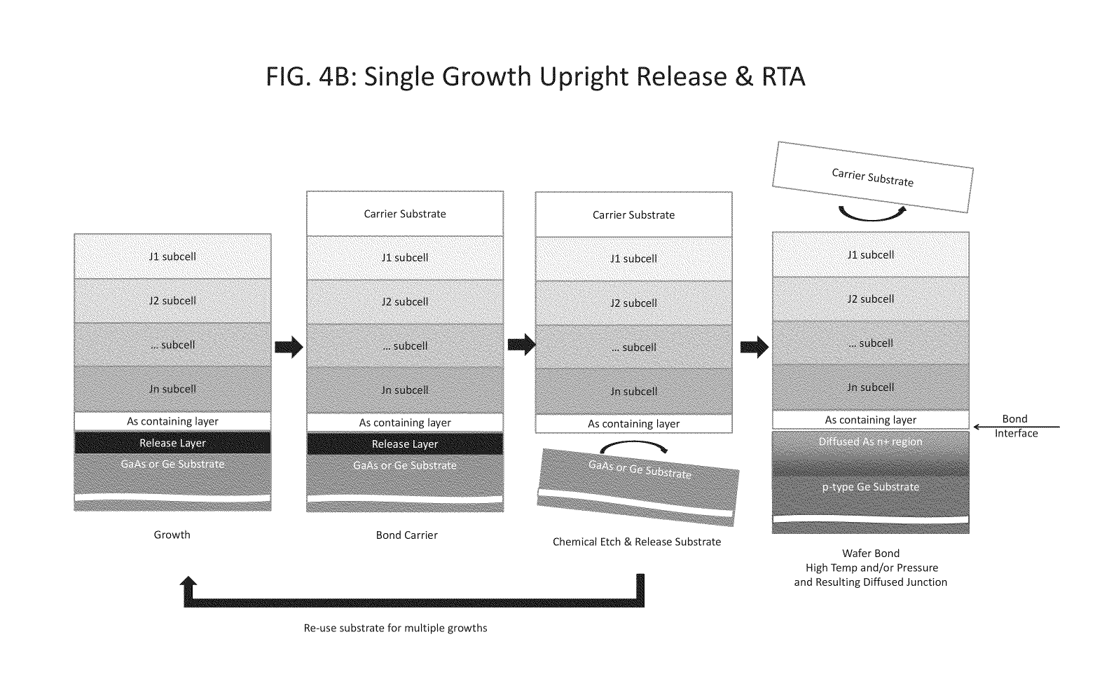

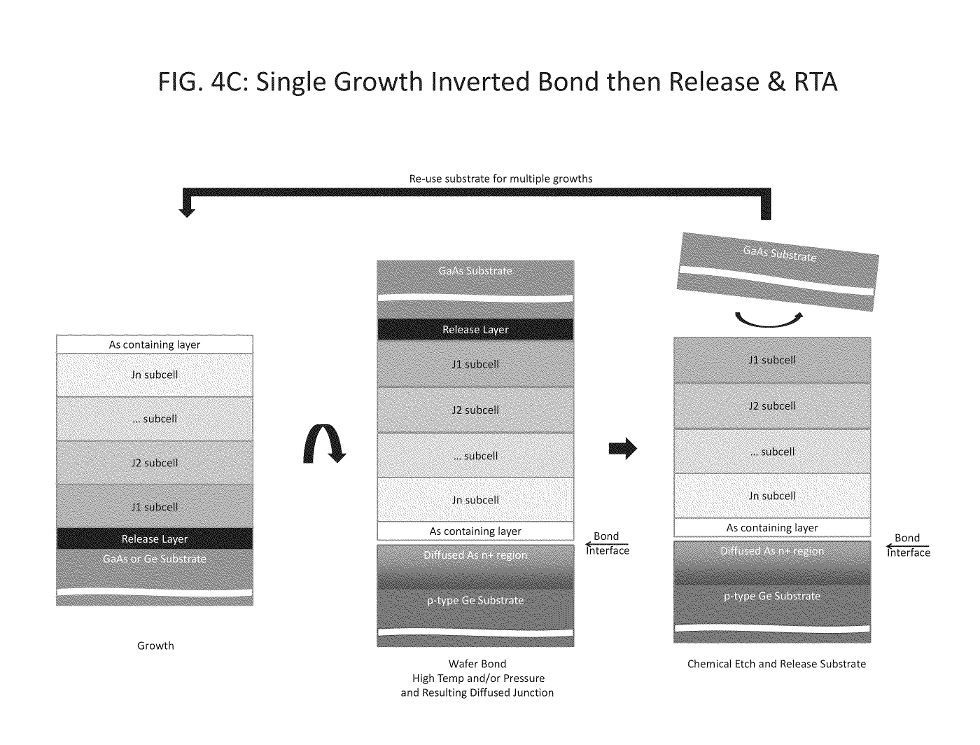

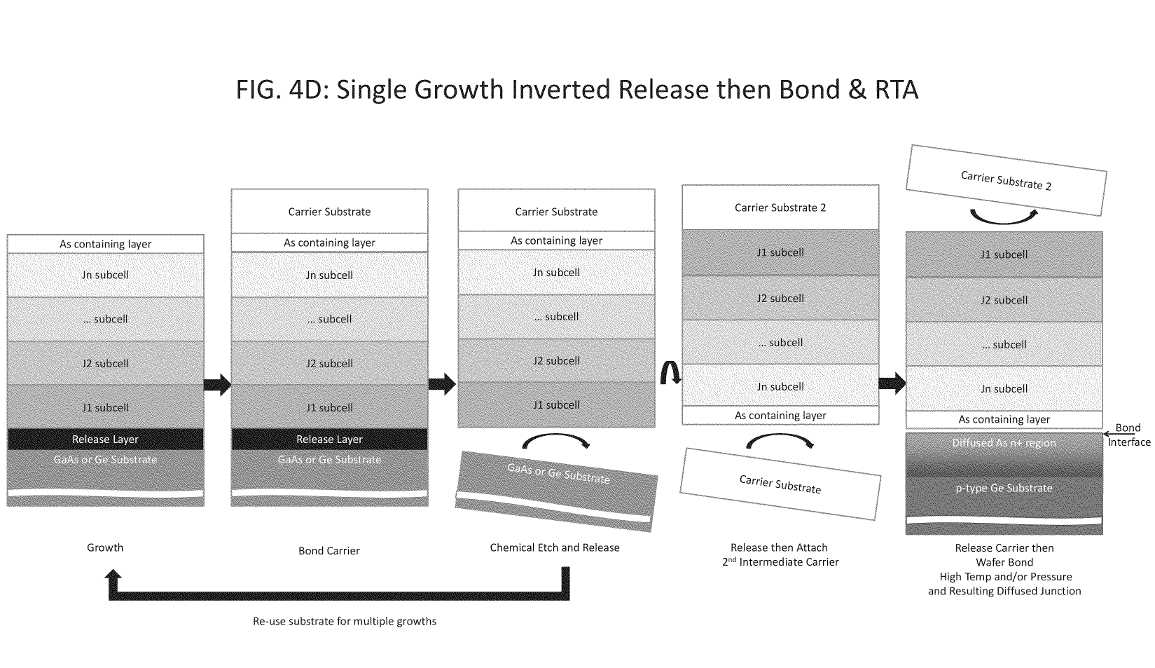

FIGS. 4A, 4B, 4C, and 4D illustrate wafer bonding processes in which As from certain subcells acts as an n+ dopant for a p-type Ge substrate due to the high wafer bonding temperature. The As diffusion can be enhanced by an additional heat treatment after the wafer bonding process in order to optimize the performance of the solar cell. In some embodiments, three or more and up to five subcells are grown on top of a GaAs substrate, with the bottom-most subcell being grown on the GaAs substrate and the uppermost subcell being J1. In some embodiments, this GaAs substrate is thinned to 50 microns, and in other embodiments, from 50 microns up to 200 microns. The three or more and up to five subcells grown on top of the GaAs substrate, after the substrate is thinned, is then wafer bonded on top of a p-type Ge substrate. During the high-temperature bonding process, the p-type Ge substrate is doped through As diffusion from the overlying GaAs to create a further subcell. This is shown in FIG. 4A.

In certain embodiments provided by the present disclosure, the subcells forming a multijunction solar cell are lattice-matched to each of the other subcells and to the substrate on which they are grown.

In other embodiments, three or more and up to five subcells are grown on top of a Ge or GaAs substrate, and a carrier substrate is attached to J1. A release layer made of AlAs or AlGaAs, with an optimal Al composition of 80%-100%, is first grown on top of the Ge or GaAs substrate. The subcells are then grown on top of the release layer. The Ge or GaAs substrate is then chemically etched and released. The three or more and up to five subcells is then wafer bonded by annealing at high temperature and pressure on top of a subcell such as a Ge subcell incorporating a p-type Ge substrate. The carrier substrate is then removed from the top of the structure. Diffusion of arsenic into the p-type Ge substrate occurs from any arsenic epitaxial layer in a neighboring subcell above the p-type Ge substrate, thereby doping the p-type Ge substrate to create a subcell from the Ge substrate. This process is shown in FIG. 4B.

Inverted growth, bonding and diffusion processes are shown in FIGS. 4C and 4D.

In certain embodiments, three or more subcells and in other certain embodiments up to five subcells, are grown on a substrate, which in certain embodiments is a Ge substrate or a GaAs substrate. In certain embodiments, J1 is grown on the Ge or GaAs substrate, J2 is grown on top of J1, and in other certain embodiments, an additional J3 is grown on J2. In yet other embodiments, a J4 can be grown on top of the J3, and J5 can be grown on J4. As shown in FIG. 4C, the release layer is grown on the substrate and the subcells are grown on the release layer. After the subcells are grown, an As-containing layer is formed on the topmost subcell, e.g., Jn as shown in FIG. 4C. The structure is then inverted and the As-containing layer is wafer bonded to a p-type Ge substrate. During the bonding process, arsenic diffuses from the As-containing layer, doping the p-type Ge substrate to form an arsenic n+ region and thereby form an additional subcell. The original GaAs or Ge substrate, which has now been inverted, is then chemically etched and released. This process is shown in FIG. 4C.

In certain embodiments, three or more subcells and in certain embodiments up to five subcells, are grown on a substrate, such as a Ge or GaAs substrate. In certain embodiments, J1 is grown on the Ge or GaAs substrate, J2 is grown on top of J1, and in other certain embodiments, an additional J3 is grown on J2. In yet other embodiments, a J4 can be grown on top of the J3, and J5 can be grown on J4. As shown in FIG. 4D, the release layer is grown on top of the substrate and the subcells are grown on the release layer. An As-containing layer can be grown on the uppermost subcell, e.g., Jn in FIG. 4D. An intermediate carrier substrate can then be bonded to the As-containing layer. As shown in FIG. 4D, the GaAs or Ge substrate is chemically etched and removed. A second carrier substrate can then be attached to the top of the structure, e.g., bonded to J1. The entire structure is then inverted, the intermediate carrier released, so that the As-containing layer can be wafer bonded to a p-type Ge substrate. Diffusion of arsenic occurs from As-containing epitaxial layer, doping the p-type Ge substrate to create an arsenic n+ region and thereby forming a subcell. The second carrier substrate, attached to J1, is then released by chemical etching. This is shown in FIG. 4D.

### Embodiments Using Single Growth P n+ Region

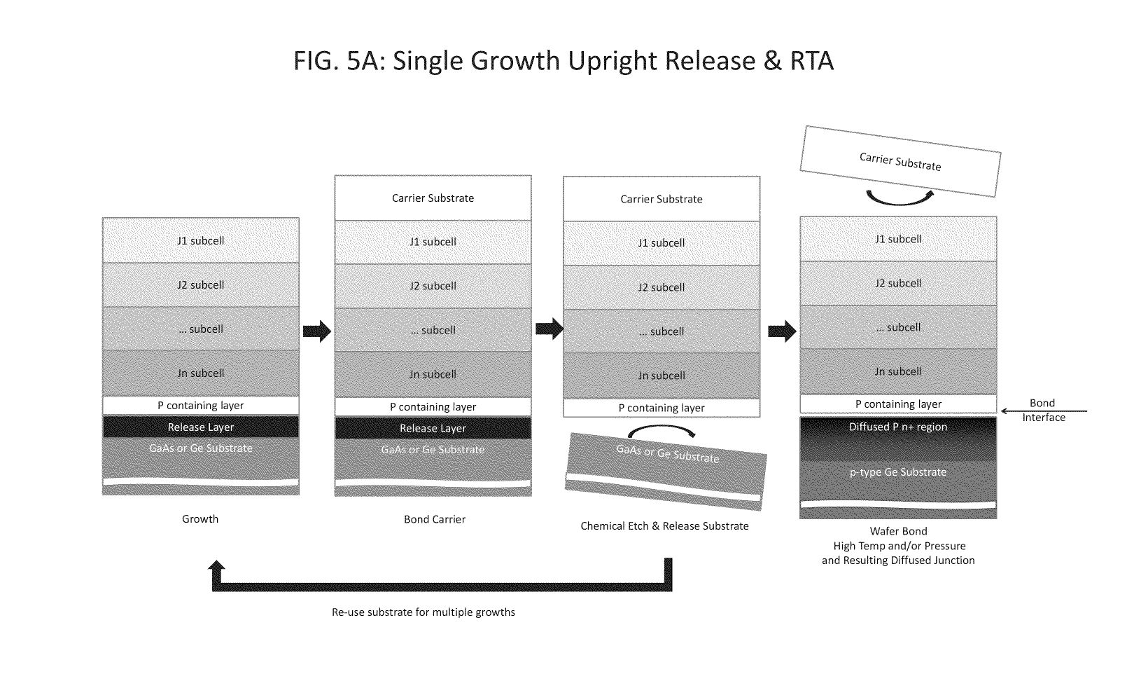

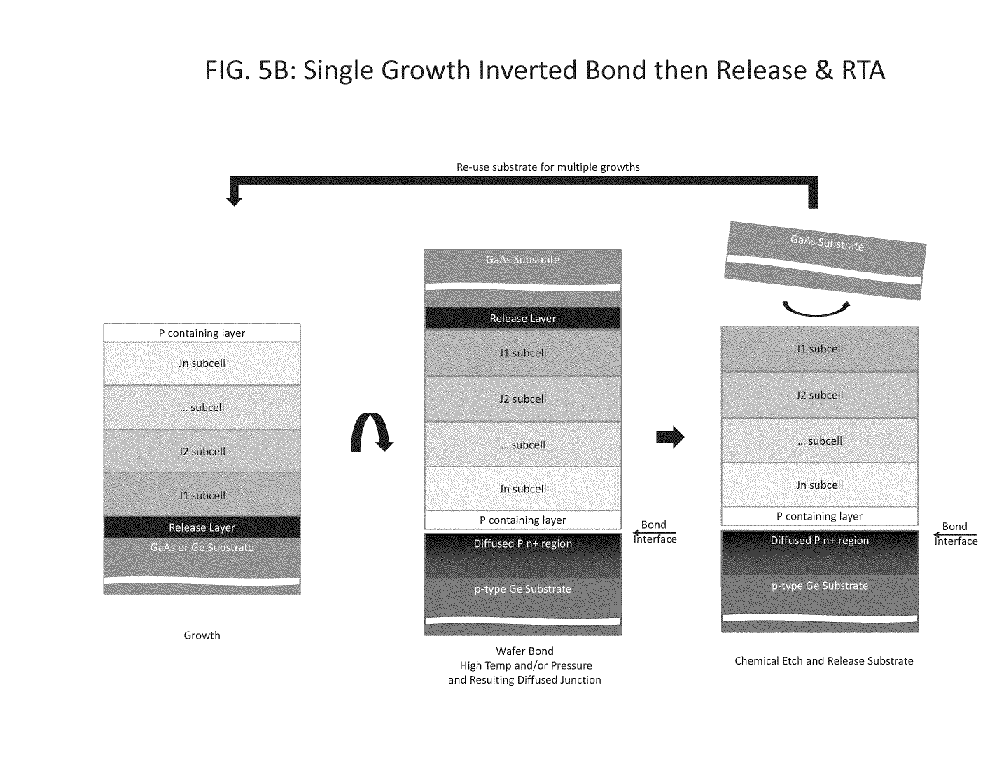

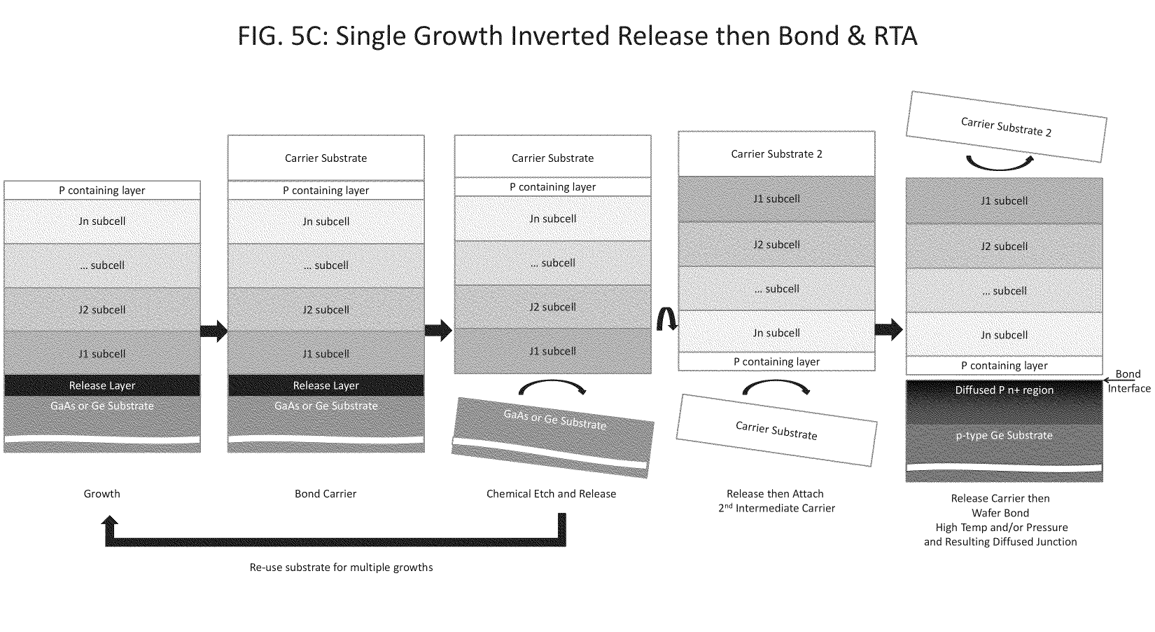

Taking advantage of high wafer bonding temperatures, the same doping via diffusion technique to create a bottom Ge subcell using P as the n-type dopant is illustrated in FIGS. 4A-D. In this method, a phosphorus-containing alloy layer selected from (Al)InGaP, InP or GaP, is formed above the release layer, which is above the GaAs or Ge substrate and is shown in FIGS. 5A-C. During the high-temperature bonding process P diffuses from the phosphorous-containing layer into the p-type Ge substrate to form a phosphorous n+ region and thereby form a subcell. The P diffusion can be enhanced by an additional heat treatment after the wafer bonding process in order to optimize the performance of the solar cell.

As shown in FIG. 5A, three or more and up to five subcells are grown on top of a phosphorous-containing layer, which is grown on a release layer grown on a Ge or GaAs substrate. A carrier substrate is bonded to J1. A release layer, which may be made of AlAs or AlGaAs, with an Al composition of 80%-100%, is applied on top of the Ge substrate or, in other embodiments, on top of the GaAs substrate. An additional alloy layer selected from (Al)InGaP, InP or GaP is grown on the release layer and below the subcells. After forming the subcells and the carrier substrate attached to the uppermost subcell, the Ge or GaAs substrate is then chemically etched and released. The three or more and up to five subcells, along with the phosphorous-containing alloy layer is then wafer bonded by annealing at high temperature and pressure on top of another Ge subcell incorporating a p-type Ge substrate. The carrier substrate is then removed from the top of the structure. Phosphorous diffuses from the phosphorous-containing layer into the p-type Ge layer to form a phosphorous n+ region and thereby form a subcell. This process is shown in FIG. 5A.

As shown in FIG. 5B, three or more subcells and in other certain embodiments up to five subcells, are grown on a substrate, such as a Ge or GaAs substrate. In certain embodiments, J1 is grown on the Ge or GaAs substrate, J2 is grown on top of J1, and in other certain embodiments, an additional J3 is grown on J2, or another J4 is grown on J3, or another J5 is grown on J4. As shown in FIG. 5B, the release, is first grown on the substrate and the subcells are grown on the release layer. A phosphorous-containing alloy layer selected from (Al)InGaP, InP, and GaP is grown as the top layer of the structure. The structure is then inverted and wafer bonded to a p-type Ge substrate, which is then doped by the n+ P diffusion from the alloy, creating a phosphorous n+ region and a Ge subcell. The original GaAs or Ge substrate, which has now been inverted, is then chemically etched and released. This is shown in FIG. 5B.

As shown in FIG. 5C, three or more subcells and in certain embodiments up to five subcells, are grown on a substrate, such as a Ge or GaAs substrate. In certain embodiments, J1 is grown on the Ge or GaAs substrate, J2 is grown on top of J1, and in other certain embodiments, an additional J3 is grown on J2, or another J4 is grown on J3, or another J5 is grown on J4. As shown in FIG. 5C, a release layer, which may be made of AlAs or AlGaAs, with an Al composition of 80%-100%, is first grown on the substrate and the subcells are grown on the release layer. A phosphorous-containing alloy layer comprising, for example, InGaP, InP, or GaP, is grown on the uppermost subcell, Jn. An intermediate carrier substrate is then bonded to the phosphorous-containing layer. The GaAs or Ge substrate is then chemically etched and removed. A second carrier substrate is then attached to the top of the structure, i.e., bonded to J1. The entire structure is then inverted, the intermediate carrier released, so that the bottom-most subcell can be wafer bonded at high temperature and pressure to a p-type Ge substrate. During the bonding process, the p-type Ge substrate becomes doped by diffusion of phosphorous from the phosphorous-containing layer to form a phosphorous n+ region and thereby form a Ge subcell. The second carrier substrate, attached to J1, is then released, for example, by chemical etching. This is shown in FIG. 5C.

### Separate Anneal

In the preferred embodiments provided by the present disclosure, the subcells forming a multijunction solar cell are lattice-matched to each of the other subcells and to the substrate on which they are grown (i.e. the substructures or subcell stacks are lattice matched).

Individual subcells, groups of subcells, and combinations of subcells and substrates, may be annealed prior to and/or after growth and/or bonding to other structures. Methods provided by the present disclosure enable substructures used to form multijunction solar cells to be annealed independent of other substructures. The substructures may be annealed at suitable temperatures and times to enhance the performance of individual subcells. For example, a substructure comprising one or more subcells formed on a first substrate may be annealed at a first temperature for a first time period, and a substructure formed on a second substrate comprising one or more subcells may be annealed at a second temperature for a second time period. After the two substructures are annealed, the substructures may be bonded and if appropriate further processed to provide a multijunction solar cell. The multijunction solar cell may also be annealed after bonding if desired.

In certain embodiments, a first group of subcells formed on a first substrate may contain a As-containing or a P-containing layer, and the As- or P-containing layer may be bonded to a p-type Ge substrate, which following diffusion of the arsenic or phosphorous forms a Ge subcell. The groups of subcells formed on a substrate may be annealed under different conditions to optimize the performance of the subcells, to improve lattice-matching, to improve reliability, or for other reasons. Independently forming groups of subcells that are later bonded to form a multijunction solar cell also facilitates the ability to grow groups of subcells under favorable or optimal conditions, where such growth conditions may not be favorable or optimal for the formation of other subcells.

The subcells can be fabricated by a number of growth techniques including MBE and chemical vapor deposition, such as MOCVD. In one embodiment, one or more subcells on a first substrate are grown by MBE, and one or more subcells are grown by MOCVD on a second substrate. After separate thermal annealing treatments, the subcells are then wafer bonded together into one multijunction solar cell.

### Embodiments Using Separate Anneal

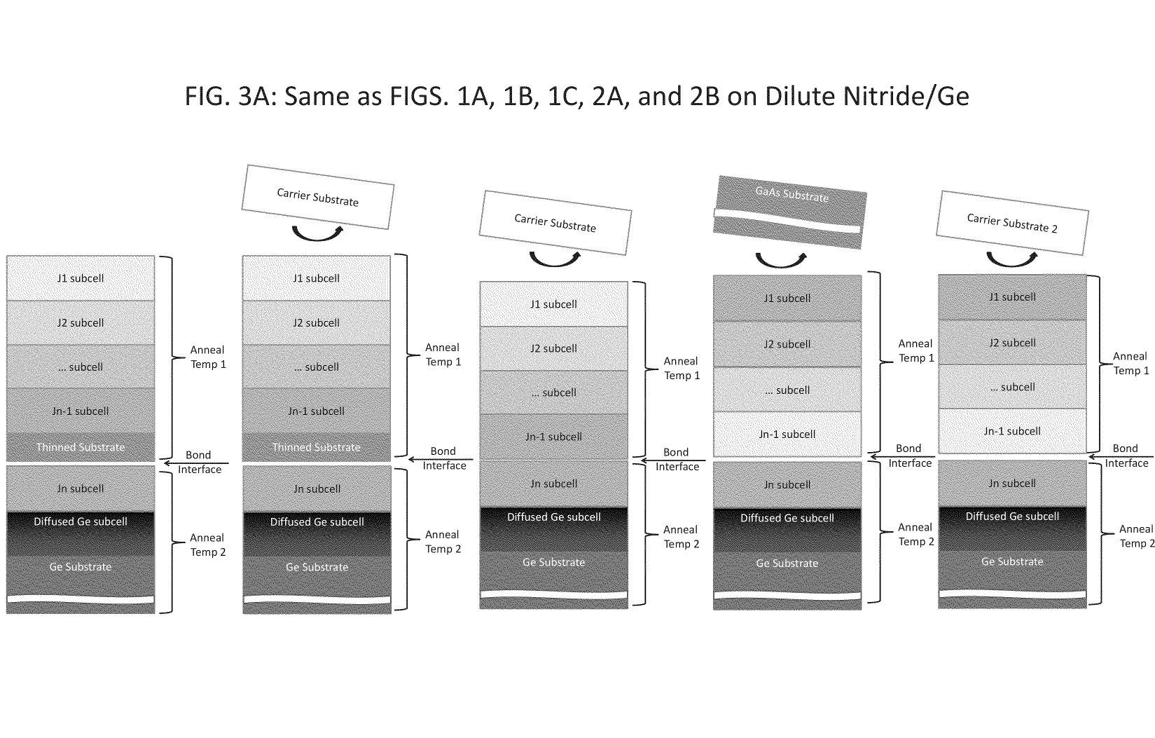

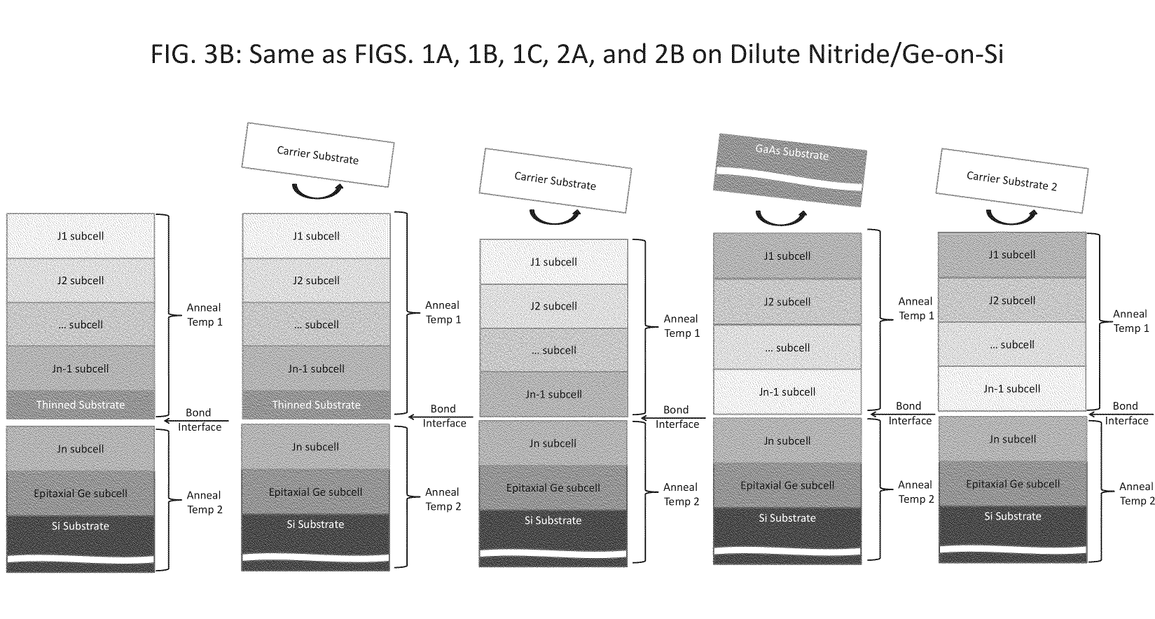

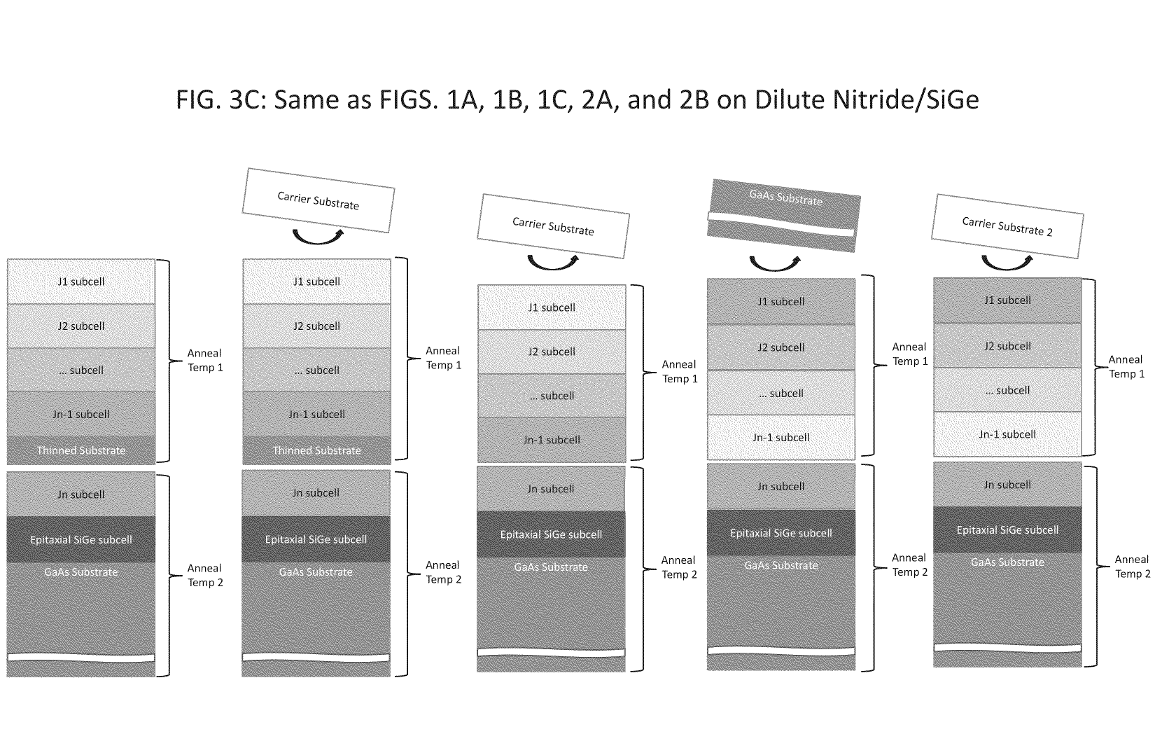

In preferred embodiments, at least one of the subcells forming a multijunction solar cell is a III-AsNV subcell as shown in FIG. 3A-C. In such embodiments, a III-AsNV subcell may be formed on one substrate, such as a Ge substrate, and other subcells formed on a second substrate, such as a GaAs substrate. The substrates may be different materials, such as InP, Ge, or Si, or they may be the same material. Further, one or more of the subcells may include the substrate, such as a Ge subcell. After formation of the subcells on their respective substrates, the individual substrates may be subjected to different or similar annealing treatments, or to no annealing treatment. The subcells and/or substrates may then be bonded together, where bonding may be directly between the exposed or top semiconductor layers on the different substrates, or where an adhesive layer may be used between the exposed semiconductor layers. Bonding may include applied heat and pressure treatments. After bonding, one or both of the substrates may be removed, such as by polishing and/or etching. Additional wafer bonds to other substrates, such as Ge, InP, or Si substrates, may then occur to add additional subcells to create three, four, five, or six junction multijunction solar cells. Tunnel junctions may exist between all subcells, and bonding may occur adjacent to or in the middle of a tunnel junction layer. Bonding may also occur adjacent to or in the middle of a layer that has minimal light absorption during solar cell operation, such as a buffer layer or a window layer of a subcell. After all of the subcells are connected and the substrates are removed as desired, then the bonded wafers undergo processing into one or more solar cell devices.

In one embodiment, the first subcell includes a first Ge substrate. The remaining subcells are formed on a separate second substrate of GaAs or Ge, including III-AsNV, (Al,In)GaAs(P), and (Al)InGaP subcells. The latter subcells may be grown in an inverted configuration, as described herein, so that the top subcell is formed first on the substrate and the second subcell formed last, or they may be formed in a standard configuration with the second subcell formed first on the substrate and the top subcell formed last. After formation of the subcells, the second substrate and subcells may be annealed via MBE or MOCVD. The first substrate and subcells may also be annealed under the same or different conditions. Subsequently, in one embodiment, bonding is done between the uppermost exposed layers of the first and second substrates. In another embodiment, bonding is done between the bottom of the second substrate and the uppermost exposed layers of the first substrate. After bonding, another thermal treatment may be applied, and one or both of the substrates may be removed. Then the bonded wafer may be processed into one or more solar cell devices.

In other embodiments, the wafer bonding occurs between a III-AsNV subcell and an (Al,In)GaAs(P) subcell, or between a III-AsNV subcell and a first InGaAs subcell, or the wafer bonding may occur between a III-AsNV subcell and a Si substrate.

In one specific, preferred embodiment, a III-AsNV subcell is grown on a Ge subcell, which incorporates a Ge substrate in-situ. The Ge subcell and Ge substrate is annealed at a certain condition of time and temperature to optimize performance of the Ge subcell as shown in FIG. 3A. Additional subcells, which may include one or more III-AsNV subcells, are grown on a different substrate and annealed at a different condition of time and temperature, and after annealing, bonded to the Ge subcell. In certain embodiments, a III-AsNV subcell is the lowermost subcell in the stack, e.g., the subcell having the lowest bandgap, and is bonded to the Ge subcell. Typically, III-AsNV subcells require an annealing temperature between 500-900° C.

In other certain embodiments, a III-AsNV subcell is grown on the carrier substrate Ge-on-Si and in-situ or post-growth annealed under certain conditions of time and temperature as shown in FIG. 3B. The Ge-on-Si carrier substrate may be fabricated by a number of known methods in the art including wafer bonding, buffering, etc. Further subcells, which may include one or more III-AsNV subcells, are grown lattice-matched on a separate substrate and annealed at a different condition and later bonded onto the III-AsNV grown on the Ge junction.

In other embodiments, a III-AsNV subcell is grown on an epitaxial SiGe subcell grown on a GaAs substrate and in-situ or post-growth annealed under a certain condition as shown in FIG. 3C. Further subcells, which may include one or more III-AsNV subcells, can be grown on a separate substrate and annealed at a different condition and later bonded onto the III-AsNV grown on the Ge subcell.

These structures as described by FIGS. 3A, 3B, and 3C, containing a III-AsNV cell, a Ge subcell, an epitaxial Ge subcell and/or a epitaxial SiGe subcell, and a substrate are wafer bonded using the methods illustrated in FIGS. 1A-C and 2A-B onto other subcells which are grown on a GaAs or Ge substrate.

In related embodiments, one or more subcells, including a Ga(In)NP(As) subcell, is on a first substrate and may be subjected to a first thermal anneal. The first substrate may be GaP or Si. One or more subcells are on one or more additional substrates, and all of the subcells are bonded together to form the multijunction solar cell. Any of the methods depicted above may be used to form the multijunction solar cell.

The invention has been explained with respect to specific embodiments. Other embodiments will be evident to those of ordinary skill in the art. Therefore, the invention is not intended to be limited, except as indicated by the appended claims.

What is claimed is:

1. A multijunction solar cell comprising:
a first group of one or more subcells; and
a second group of one or more subcells, wherein each of the subcells is lattice matched to a second substrate 1;
wherein:
the second group of subcells is bonded to the first group of subcells;
the multijunction solar cell comprises at least three subcells; and
at least one of the at least three subcells comprises a base layer comprising an alloy of elements of group IIIA, group IV, and group VA on the periodic table.

2. The multijunction solar cell of claim 1, wherein each of the first group of subcells is lattice matched to a first substrate.

3. The multijunction solar cell of claim 2, wherein the first substrate comprises a material selected from Ge, GaAs, and p-type Ge.

4. The multijunction solar cell of claim 2, wherein the first substrate comprises a material selected from Ge, SiGe, GaAs, and InP.

5. The multijunction solar cell of claim 2, wherein the first substrate comprises a material selected from Ge and GaAs; and the first group of subcells comprises a III-AsNV subcell grown on the first substrate.

6. The multijunction solar cell of claim 5, wherein at least one III-AsNV subcell comprises a GaInAsSb alloy.

7. The multijunction solar cell of claim 1, wherein the first group of subcells comprises an epitaxial Ge substrate overlying a Si substrate.

8. The multijunction solar cell of claim 1, wherein
the second substrate comprises a thinned substrate; and
the thinned substrate is bonded to the first group of subcells.

9. The multijunction solar cell of claim 1, wherein,
the second substrate is removed from the second group of subcells; and
the second group of subcells is bonded to the first group of subcells.

10. The multijunction solar cell of claim 1, wherein,
the first group of subcells is annealed at a first condition;
the second group of subcells is annealed at a second condition; and
the first condition is different than the second condition.

11. The multijunction solar cell of claim 1, wherein the second substrate is thinned before annealing the second group of subcells.

12. The multijunction solar cell of claim 1, wherein the second substrate is removed before annealing the second group of subcells.

13. The multijunction solar cell of claim 1, wherein the first group of subcells further comprises a diffused junction layer overlying the uppermost subcell.

14. The multijunction solar cell of claim 1, wherein the second group of subcells further comprises an As-containing layer underlying the lowermost subcell.

15. The multijunction solar cell of claim 1, wherein,
the first group of subcells comprises a p-type Ge substrate;
the second group of subcells comprises a thinned substrate; and
the thinned substrate is bonded to the Ge substrate.

16. The multijunction solar cell of claim 1, wherein,
the first group of subcells comprises a p-type Ge substrate;
the second group of subcells comprises an As-containing layer underlying the lowermost subcell; and the As-containing layer is bonded to the Ge substrate.

17. The multijunction solar cell of claim 1, wherein,
the first group of subcells comprises a p-type Ge substrate;
the second group of subcells comprises a phosphorous-containing layer selected from InGaP, InP, and GaP underlying the lowermost subcell; and
the phosphorous-containing layer is bonded to p-type Ge substrate.

18. The multijunction solar cell of claim 1, wherein the second substrate comprises a material selected from GaAs and Ge.

19. The multijunction solar cell of claim 1, wherein the second group of subcells is grown on a release layer overlying the second substrate.

20. The multijunction solar cell of claim 19, wherein the release layer comprises a material selected from AlAs and AlGaAs, wherein the Al content is greater than 80%.

21. The multijunction solar cell of claim 1, wherein the first group of subcells comprises a subcell selected from a Ge subcell and a SiGe subcell.

22. The multijunction solar cell of claim 1 wherein each of the at least three subcells comprises a base layer independently selected from Al)InGaP, (Al)GaAs, InGaAsP, AlInGaAs, InGaAs, InP, Ga(In)As, and (Al)GaAs.

23. The multijunction solar cell of claim 1, wherein the second substrate comprises a material selected from Ge, SiGe, GaAs, and InP

24. A method of manufacturing a multijunction solar cell, comprising:
forming a first group of one or more subcells;
forming a second group of one or more subcells, wherein each of the one or more subcells is lattice matched to a second substrate;
thinning the second substrate; and
bonding the thinned second substrate to a top subcell of the first group of subcells, to form a multijunction solar cell;
wherein:
the multijunction solar cell comprises at least three subcells; and
at least one of the at least three subcells comprises a base layer comprising an alloy of elements of group IIIA, group IV, and group VA on the periodic table.

25. The method of claim 24, wherein each of the one or more subcells of the first group of subcells is lattice matched to a first substrate.

26. The method of claim 24, comprising attaching a carrier substrate d to a top subcell of the second group of subcells before thinning the second substrate.

27. The method of claim 24, wherein the first group of subcells is annealed at a first condition; and the second group of subcells is annealed at a second condition before bonding.

28. A method of manufacturing a multijunction solar cell, comprising:
forming a first group of one or more subcells;
forming a second group of one or more subcells overlying a release layer, wherein the release layer overlies a second substrate, and each of the one or more subcells is lattice matched to the second substrate;
attaching a carrier substrate to a top subcell of the second group of subcells;
releasing the second group of subcells from the second substrate; and
bonding the second group of subcells to a top subcell of the first group of subcells, to form a multijunction solar cell;
wherein:
the multijunction solar cell comprises at least three subcells; and
at least one of the at least three subcells comprises a base layer comprising an alloy of elements of group IIIA, group IV, and group VA on the periodic table.

29. The method of claim 28, wherein each of the one or more subcells of the first group of subcells is lattice matched to a first substrate.

30. The method of claim 28, wherein forming the second group of subcells comprises forming the second group of subcells on the release layer.

31. The method of claim 28, wherein bonding comprises bonding a subcell having the lowest bandgap of the second group of subcells to a top subcell of the first group of subcells,

32. The method of claim 28, wherein the second group of subcells is formed in a non-inverted order.

33. The method of claim 28, wherein the second group of subcells is formed in an inverted order.

34. The method of claim 28, wherein,
the first group of subcells is annealed at a first condition; and
the second group of subcells is annealed at a second condition before bonding.

35. The method of claim 28, further comprising:
forming an As-containing layer overlying the release layer;
forming the second group of subcells comprises forming the second group of subcells on the As-containing layer; and
bonding comprises bonding the As-containing layer to the top subcell of the first group of subcells.

36. The method of claim 28, further comprising:
forming an P-containing layer overlying the release layer;
forming the second group of subcells comprises forming the second group of subcells on the P-containing layer; and
bonding comprises bonding the P-containing layer to the top subcell of the first group of subcells.

37. The method of claim 36 wherein the P-containing layer comprises an alloy selected from InGaP, InP, and GaP.
